(19) United States
(12) Patent Application Publication
(10) Pub. No.: US 2017/0301534 A1
(43) Pub. Date: Oct. 19, 2017

(54) SUBSTRATE LIQUID PROCESSING METHOD, SUBSTRATE LIQUID PROCESSING APPARATUS, AND COMPUTER-READABLE STORAGE MEDIUM THAT STORES SUBSTRATE LIQUID PROCESSING PROGRAM

(71) Applicant: Tokyo Electron Limited, Tokyo (JP)

(72) Inventors: Mitsunori Nakamori, Kumamoto (JP); Teruomi Minami, Kumamoto (JP); Kotaro Ooishi, Kumamoto (JP); Jun Nonaka, Kumamoto (JP)

(73) Assignee: Tokyo Electron Limited, Tokyo (JP)

(21) Appl. No.: 15/518,013

(22) PCT Filed: Oct. 20, 2015
(86) PCT No.: PCT/JP2015/079616

§ 371 Date: Apr. 10, 2017

(30) Foreign Application Priority Data
Oct. 21, 2014 (JP) 2014-214410
Sep. 8, 2015 (JP) 2015-176524

(51) Int. Cl. H01L 21/02; B08B 3/10; B08B 3/04; B08B 3/08; H01L 21/687; H01L 21/67

(52) U.S. Cl. CPC H01L 21/02052; H01L 21/68764; H01L 21/67051; B08B 3/041; B08B 3/08; B08B 3/10

(57) ABSTRACT

This liquid treatment method for substrates involves performing: a liquid treatment step for liquid-treating a substrate with a treatment liquid; a rinse treatment step for rinsing the liquid-treated substrate with a rinsing liquid; a water-repellency treatment step for subjecting the rinsed substrate to a water-repellency treatment using a water-repellency-imparting solution; next, a substitution treatment step for subjecting the substrate subjected to the water-repellency treatment to a substitution treatment acceleration liquid; a cleaning treatment step for cleaning the substrate subjected to the water-repellency treatment by using a cleaning solution; and thereafter, a drying treatment step for substituting the cleaning solution with a drying solution having a higher volatility than that of the cleaning solution, and removing the drying solution from the substrate. Thus, it is possible to prevent pattern collapse during the drying treatment, and to decrease particles caused by watermarks.

### TECHNICAL FIELD

The present disclosure relates to a substrate liquid processing method and a substrate liquid processing apparatus for performing a water-repellency processing on a surface of a liquid-processed substrate with a water-repellent liquid and then drying the surface, and also relates to a computer-readable storage medium that stores a substrate liquid processing program.

### BACKGROUND

Conventionally, in manufacturing, for example, semiconductor parts or flat panel displays, a substrate liquid processing apparatus is used to perform a liquid processing on a substrate such as, for example, a semiconductor wafer or a liquid crystal substrate, using various processing liquids, and thereafter, perform a drying processing of removing a processing liquid remaining on the substrate by rotating the substrate at a high speed.

In the substrate liquid processing apparatus, with the miniaturization of patterns such as, for example, circuit patterns and etching mask patterns formed on the surface of the substrate and the increase in aspect ratio, the patterns formed on the surface of the substrate may collapse due to the action of the surface tension of the processing liquid remaining on the substrate during the drying processing.

Therefore, in the conventional substrate liquid processing apparatus, a water repellent liquid (e.g., a silylating agent) is supplied to the substrate to impart water-repellency to the surface of the substrate when the drying processing is performed. Thereafter, deionized water is supplied as a cleaning liquid to the substrate, and the substrate is rotated at a high speed to remove the cleaning liquid from the surface thereof. As described above, in the conventional substrate liquid processing apparatus, the surface of the substrate is imparted with water-repellency, so that the contact angle between the patterns and the rinsing liquid is brought into a state close to 90 degrees. Thus, the force for collapsing the pattern with the cleaning liquid is reduced, thereby suppressing the collapse of the patterns during the drying processing (see Patent Document 1).

According to the above-described method, since the surface of the substrate is made water-repellent by the water-repellent liquid, the rinse liquid is liable to remain as water droplets as compared with a hydrophilic substrate. As a result, when the drying of the substrate proceeds as it is, a watermark is formed on the surface of the substrate, which may cause particles. For this reason, what is demanded is a technique that reduces particles while suppressing a pattern from collapsing during the drying processing.

### PRIOR ART DOCUMENT

### Patent Document

Patent Document 1: Japanese Patent Laid-Open Publication No. 2010-114439

### DISCLOSURE OF THE INVENTION

### Problems to be Solved

The present disclosure is to provide a technique capable of reducing particles caused by a watermark while suppressing a pattern from collapsing during a drying processing.

### Means to Solve the Problems

According to an exemplary embodiment, the present disclosure provides a substrate liquid processing method including: performing a liquid processing step of liquid-processing a substrate with a processing liquid, a rinse processing step of rinsing the liquid-processed substrate with a rinse liquid, and a water-repellency processing step of imparting water-repellency to the rinsed substrate with a water-repellent liquid; then, performing a replacement processing step of replacing the water-repellency-imparted substrate with a replacement promoting liquid, and a cleaning processing step of cleaning the water-repellency-imparted substrate with a cleaning liquid; and then, performing a drying processing step of replacing the cleaning liquid with a drying liquid having a higher volatility than that of the cleaning liquid and removing the drying liquid from the substrate.

The cleaning liquid may be deionized water, and the drying liquid and the replacement promoting liquid may be isopropyl alcohol (IPA).

A flow rate of the replacement promoting liquid supplied to the substrate in the replacement processing step may be higher than a flow rate of the drying liquid supplied to the substrate in the drying processing step.

In the drying processing step, the drying liquid may be supplied to the substrate in a lower humidity state than that of the cleaning treatment step.

The replacement processing step and the cleaning processing step may be performed at the same time.

The replacement promoting liquid, the cleaning liquid, and the drying liquid may be supplied to the substrate from the same nozzle.

The replacement promoting liquid and the cleaning liquid may be supplied to the substrate by changing a mixing ratio thereof stepwise or continuously at a time of transition from the replacement processing step to the cleaning processing step.

The cleaning liquid and the drying liquid may be supplied to the substrate by changing a mixing ratio thereof stepwise or continuously at a time of transition from the cleaning processing step to the drying processing step.

The drying processing step may include steps of; forming, on the substrate, a streak-like flow of the cleaning liquid toward an outer peripheral edge of the substrate at a supply position where the cleaning liquid is supplied onto the substrate; and supplying the drying liquid to a position closer to a central side of the substrate than the supply position of the cleaning liquid.

The step of forming the streak-like flow of the cleaning liquid may include a step of moving the supply position of the cleaning liquid from the central side of the substrate to the outer peripheral side.

According to another exemplary embodiment, the present disclosure provides a substrate liquid processing apparatus including: a substrate holding unit that holds a substrate; a processing liquid supply unit that supplies a processing liquid to the substrate; a rinse liquid supply unit that supplies a rinse liquid to the substrate liquid-processed with the processing liquid; a water-repellent liquid supply unit that supplies a water-repellent liquid to the substrate rinsed with the rinse liquid; a replacement promoting liquid supply unit that supplies a replacement promoting liquid to the substrate imparted with water-repellency with the water-repellent liquid; a cleaning liquid supply unit that supplies a cleaning liquid to the substrate processed with the replacement promoting liquid; a drying liquid supply unit that supplies a drying liquid having a higher volatility that that of the cleaning liquid to the substrate cleaned with the cleaning liquid; and a controller that performs a control to supply the replacement promoting liquid from the replacement promoting liquid supply unit to the substrate imparted with water-repellency with the water-repellent liquid, supply the cleaning liquid from the cleaning liquid supply unit to the substrate, supply the drying liquid from the drying liquid supply unit to the substrate, and then, remove the drying liquid from the substrate.

The controller performs a control to supply the replacement processing liquid from the replacement promoting liquid supply unit to the substrate at a flow rate higher than a flow rate of the drying liquid to be supplied from the drying liquid supply unit to the substrate.

The substrate liquid processing apparatus may further include a dry air supply unit that supplies dry air to the substrate. In this case, the controller may cause the dry air to be supplied from the dry air supply unit to the substrate when the drying liquid is supplied from the drying liquid supply unit to the substrate.

The controller may perform a control to supply the replacement promoting liquid from the replacement promoting liquid supply unit to the substrate and simultaneously supply the cleaning liquid from the cleaning liquid supply unit.

The replacement promoting liquid, the cleaning liquid, and the drying liquid may be supplied to the substrate from the same nozzle.

The replacement promoting liquid and the cleaning liquid may be supplied to the substrate by changing a mixing ratio thereof stepwise or continuously at a time of transition from the supply of the replacement processing liquid to the supply of the cleaning processing liquid.

The cleaning liquid and the drying liquid may be supplied to the substrate by changing a mixing ratio thereof stepwise or continuously at a time of transition from the supply of the cleaning processing liquid to the supply of the drying processing liquid.

At the time of transition from supply of the cleaning liquid to supply of the drying liquid, a streak-like flow of the cleaning liquid is formed on the substrate at a supply position where the cleaning liquid is supplied onto the substrate toward an outer peripheral edge of the substrate, and the drying liquid may be supplied to a position closer to a central side of the substrate than the supply position of the cleaning liquid.

The supply position of the cleaning liquid forming the streak-like flow may be moved from the central side of the substrate to the outer peripheral side.

According to still another exemplary embodiment, the present disclosure provides non-transitory computer-readable storage medium that stores a substrate liquid processing program that, when executed, to cause a computer to perform a processing on a substrate using a substrate liquid processing apparatus including: a substrate holding unit that holds a substrate; a processing liquid supply unit that supplies a processing liquid to the substrate; a rinse liquid supply unit that supplies a rinse liquid to the substrate liquid-processed with the processing liquid; a water-repellent liquid supply unit that supplies a water-repellent liquid to the substrate rinsed with the rinse liquid; a replacement promoting liquid supply unit that supplies a replacement promoting liquid to the substrate imparted with water-repellency with the water-repellent liquid; a cleaning liquid supply unit that supplies a cleaning liquid to the substrate processed with the replacement promoting liquid; a drying liquid supply unit that supplies a drying liquid having a higher volatility that that of the cleaning liquid to the substrate cleaned with the cleaning liquid; and a controller that controls the units. A control is performed to supply the replacement promoting liquid from the replacement promoting liquid supply unit to the substrate imparted with water-repellency with the water-repellent liquid, supply the cleaning liquid from the cleaning liquid supply unit to the substrate, supply the drying liquid from the drying liquid supply unit to the substrate, and then, remove the drying liquid from the substrate.

### BRIEF DESCRIPTION OF THE DRAWINGS

FIG. 1 is a plan view illustrating a substrate liquid processing apparatus.

FIG. 2 is a side view illustrating a substrate liquid processing unit.

FIG. 3 is an explanatory view illustrating a nozzle group.

FIG. 4 is a flowchart illustrating a substrate liquid processing method.

FIGS. 5A and 5B are explanatory views illustrating the substrate liquid processing method (FIG. 5A illustrates a liquid processing step, and FIG. 5B illustrates a rinse processing step).

FIGS. 6A and 6B are explanatory views illustrating the substrate liquid processing method (FIG. 6A illustrates a first replacement processing step, and FIG. 6B illustrates a water-repellency processing step).

FIGS. 7A and 7B are explanatory views illustrating the substrate liquid processing method (FIG. 7A illustrates a second replacement processing step, and FIG. 7B illustrates a cleaning processing step).

FIGS. 8A and 8B are explanatory views illustrating the substrate liquid processing method (FIG. 8A illustrates a drying liquid supply step, and FIG. 8B illustrates a drying liquid removal step).

FIGS. 9A to 9D are explanatory views illustrating the substrate liquid processing method.

### DETAILED DESCRIPTION TO EXECUTE THE INVENTION

Hereinafter, a specific exemplary embodiment of the substrate liquid processing apparatus and the substrate liquid processing method according to the present disclosure will be described with reference to the drawings.

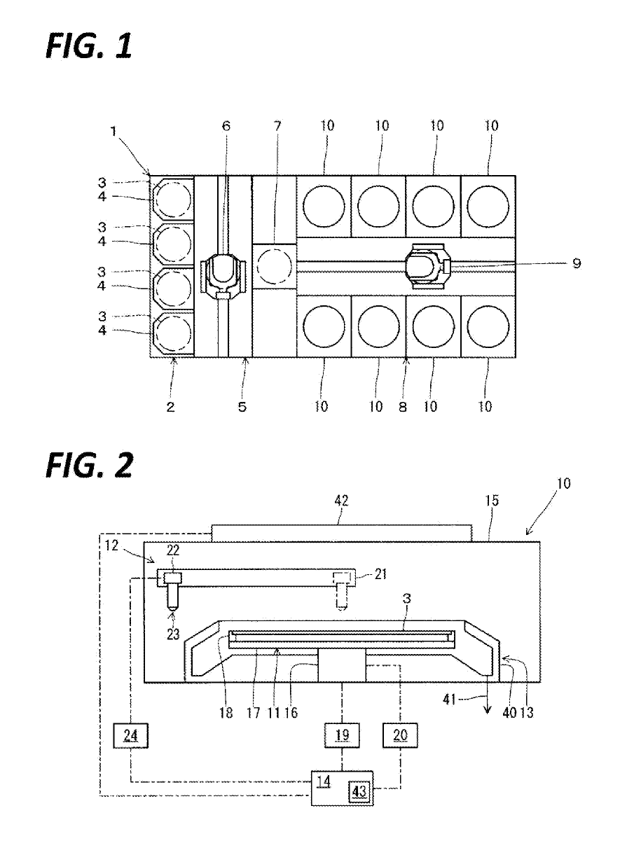

As illustrated in FIG. 1, the substrate liquid processing apparatus 1 includes a carry-in/out section 2 at the front end. Carriers 4 each accommodating a plurality of (e.g., twenty five (25)) substrates 3 (in this case, semiconductor wafers) are carried into and carried out and are placed from side to side in the carry-in/out section 2.

Further, the substrate liquid processing apparatus 1 includes a conveyance section 5 at the rear side of the carry-in/out section 2. A substrate conveyance device 6 is disposed on the front side of the conveyance section 5, and a substrate delivery table 7 is disposed on the rear side. In the conveyance section 5, a substrate 3 is conveyed between any one of the carriers 4 placed in the carry-in/out section 2 and the substrate delivery table 7 by using the substrate conveyance device 6.

Further, the substrate liquid processing apparatus 1 includes a processing section 8 on the rear side of the conveyance section 5. A substrate conveyance device 9 is arranged at the center of the processing section 8 to extend in the back and forth direction. Substrate liquid processing units 10 for liquid-processing the substrates 3 are arranged side by side in the back and forth direction on both left and right sides of the substrate conveyance device 9. In the processing section 8, the substrate 3 is conveyed between the substrate delivery table 7 and one of the substrate liquid processing units 10 by using the substrate conveyance device 9, and the substrate liquid processing is performed on the substrate 3 by using the substrate liquid processing unit 10.

As illustrated in FIG. 2, the substrate liquid processing unit 10 includes a substrate holding unit 11, a supply unit 12, and a recovery unit 13, which are controlled by a controller 14. The substrate holding unit 11 rotates the substrate 3 while holding the substrate 3. The supply unit 12 supplies various liquids or gases to the substrate 3. The recovery unit 13 recovers the various liquids or gases supplied to the substrate 3. The controller 14 controls the operation of the substrate liquid processing unit 10, as well as the operation of the entire substrate liquid processing apparatus 1.

The substrate holding unit 11 includes a rotating shaft 16 that vertically extends substantially in the center of the inside of a processing chamber 15. A disk-shaped turntable 17 is horizontally attached to the upper end of the rotating shaft 16. A plurality of substrate holders 18 are attached to the outer peripheral edge of the turntable 17 at regular intervals in the circumferential direction.

The rotating shaft 16 is connected with a substrate rotating mechanism 19 and a substrate lifting mechanism 20. The rotating operation of the substrate rotating mechanism 19 and the lifting operation of the substrate lifting mechanism 20 are controlled by the controller 14.

The substrate holding unit 11 holds the substrate 3 horizontally with the substrate holders 18 of the turntable 17. Further, the substrate holding unit 11 rotates the substrate 3 held by the turntable 17 by driving the substrate rotating mechanism 19. Further, the substrate holding unit 11 lifts the turntable 17 and the substrate 3 by driving the substrate lifting mechanism 20.

The supply unit 12 includes a guide rail 21 provided inside the processing chamber 15, an arm 22 movably attached to the guide rail 21, a nozzle group 23 including a plurality of nozzles attached to a lower portion of the tip of the arm 22. The arm 22 is connected with a nozzle moving mechanism 24 driven and controlled by the controller 14.

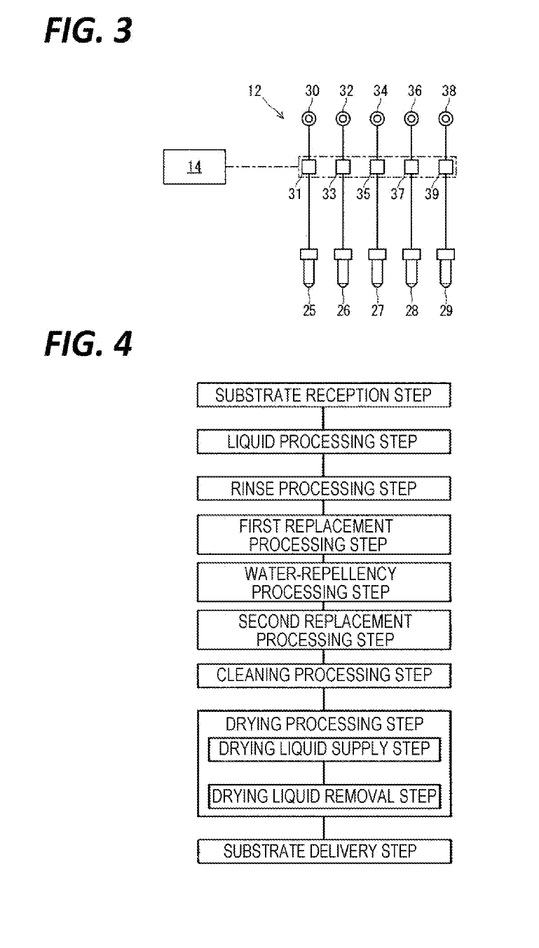

As illustrated in FIG. 3, the nozzle group 23 includes a processing liquid supply nozzle 25, a deionized water supply nozzle 26, an IPA supply nozzle 27, a water-repellent liquid supply nozzle 28, and an inert gas supply nozzle 29. The processing liquid supply nozzle 25 is connected with a processing liquid source 30 via a flow rate adjustor 31 to supply a processing liquid (here, a chemical liquid for cleaning). The deionized water liquid supply nozzle 26 is connected with a deionized water liquid source 32 via a flow rate adjustor 33 to supply deionized water. The IPA supply nozzle 27 is connected with an IPA source 34 via a flow rate adjustor 35 to supply isopropyl alcohol (IPA). The water-repellent liquid supply nozzle 28 is connected with a water-repellent liquid source 36 via a flow rate adjustor 37 to supply a water-repellent liquid (here, a silylating agent). The inert gas supply nozzle 29 is connected with an inert gas source 38 via a flow rate adjustor 39 to supply an inert gas (here, nitrogen gas). The flow rate and the opening/closing of each of the flow rate adjustors 31, 33, 35, 37, 39 are controlled by the controller 14. Carbon dioxide gas may be previously dissolved in the deionized water to be supplied from the deionized water supply nozzle 26. Therefore, generation of static electricity may be suppressed when the deionized water flows on the surface of the substrate 3. Even though static electricity is generated on the surface of the substrate 3, the static electricity may be removed.

The supply unit 12 horizontally moves the nozzles 25 to 29 between a standby position outside the outer peripheral edge of the substrate 3 and a start position above the central portion of the substrate 3 by the nozzle moving mechanism 24. Further, the supply unit 12 ejects the liquid or gas at a predetermined flow rate adjusted by the flow rate adjustors 31, 33, 35, 37, 39 from the nozzles 25 to 29 toward the surface (upper surface) of the substrate 3. A plurality of arms 22 may be provided to be movable independently from each other, and one or more of the nozzles 25 to 29 may be distributed and attached to each arm. All of the nozzles 25 to 29 may be arranged on a single common arm.

Further, instead of providing the deionized water supply nozzle 26 and the IPA supply nozzle 27, it is also possible to provide one supply nozzle for supplying both deionized water and IPA, which may be configured to continuously perform the switch from the IPA supply to the deionized water supply and the switch from the deionized water supply to the IPA supply. Therefore, during the switching of the deionized water and the IPA, the surface of the substrate 3 may be suppressed from being exposed such that the surface of the substrate 3 hardly comes into contact with the surrounding atmosphere (surrounding gas).

As illustrated in FIG. 2, the recovery unit 13 includes an annular recovery cup 40 arranged around the turntable 17. An opening, which is slightly larger than the turntable 17 (substrate 3), is formed in the upper end portion of the recovery cup 40. A drain 41 is connected to the lower end portion of the recovery cup 40.

The recovery unit 13 recovers, for example, the processing liquid supplied to the surface of the substrate 3 by the recovery cup 40 and discharges the processing liquid from the drain 41 to the outside. The drain 41 recovers not only the liquid, but also the gas (atmosphere) inside the processing chamber 15. Therefore, clean air supplied from a fan filter unit (FFU) 42 provided in the upper portion of the processing chamber 15 is caused to flow down inside the processing chamber 15. The FFU 42 is configured to perform the switching between a state of supplying the clean air and a state of supplying clean dry air (CDA) having a humidity lower than that of the clean air. The humidity inside the processing chamber 15 (around the substrate 3) may be lowered by causing the CDA to flow down inside the processing chamber 15. Therefore, the FFU 42 functions as a dry gas supply unit that supplies CDA as a dry gas to the inside of the processing chamber 15. The FFU 42 is driven and controlled by the controller 14.

The substrate liquid processing apparatus 1 is configured as described above and controlled by the controller 14 in accordance with various programs stored in a storage medium 43 provided in the controller 14 (computer), thereby performing a processing on the substrate 3. Here, the storage medium 43 stores various setting data and programs, and is constituted by any known storage medium such as, for example, a memory (e.g., a ROM or a RAM) or a disk-like storage medium (e.g., a hard disk, a CD-ROM, a DVD-ROM, or a flexible disk).

Then, the substrate liquid processing apparatus 1 performs a processing on the substrate 3 as described below (see, e.g., FIG. 4) in accordance with the substrate liquid processing program stored in the storage medium 43.

First, the substrate liquid processing apparatus 1 receives the substrate 3 to be conveyed by the substrate conveyance device 9, by the substrate liquid processing unit 10 (substrate reception step).

In the substrate reception step, the controller 14 moves up the turntable 17 to a predetermined position. Then, one substrate 3 conveyed from the substrate conveyance device 9 to the inside of the processing chamber 15 is received in a state of being held horizontally by the substrate holders 18. Thereafter, the turntable 17 is moved down to a predetermined position. In the substrate reception step, the nozzle group 23 (including the processing liquid supply nozzle 25, the deionized water supply nozzle 26, the IPA supply nozzle 27, the water-repellent liquid supply nozzle 28, and the inert gas supply nozzle 29) is retreated to the standby position outside the outer periphery of the turntable 17.

Next, the substrate liquid processing apparatus 1 performs a liquid processing on the surface of the substrate 3 with a processing liquid such as, for example, an etching liquid or a cleaning liquid (liquid processing step).

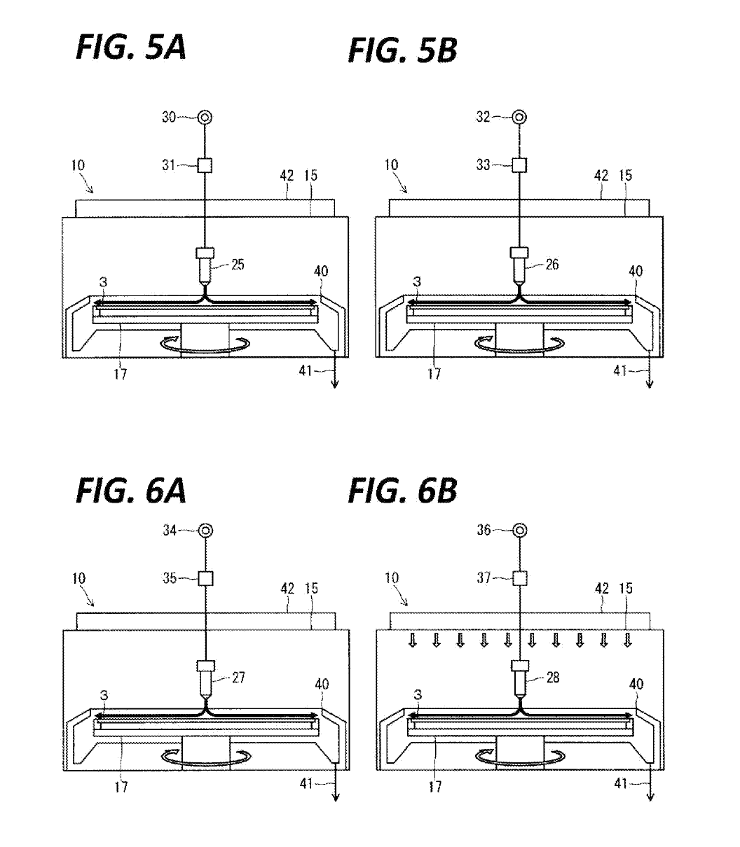

In the liquid processing step, as illustrated in FIG. 5A, the controller 14 moves the processing liquid supply nozzle 25 to the start position above the central portion of the substrate 3. Further, the substrate 3 is rotated by rotating the turntable 17 at a predetermined rotation speed. Thereafter, the processing liquid whose flow rate has been adjusted to a predetermined flow rate by the flow rate adjustor 31 is supplied from the processing liquid source 30 to the processing liquid supply nozzle 25, and ejected from the processing liquid supply nozzle 25 toward the surface (upper surface) of the substrate 3. Thus, the surface of the substrate 3 is liquid-processed with the processing liquid. The processing liquid supplied to the substrate 3 is shaken off to the outside of the outer peripheral edge of the substrate 3 by the centrifugal force of the rotating substrate 3, recovered by the recovery cup 40, and discharged to the outside from the drain 41. After the processing liquid is supplied for a predetermined time, the ejection of the processing liquid is stopped by the flow rate adjustor 31. As such, in the liquid processing step, the processing liquid supply nozzle 25, the flow rate adjustor 31, and the processing liquid source 30 mainly function as the processing liquid supply unit. In the liquid processing step, clean air or CDA is selected as a gas to be supplied from the FFU 42 depending on the type of the processing liquid, and the inside of the processing chamber 15 is maintained at a high degree of cleanliness.

Next, the substrate liquid processing apparatus 1 performs a rinse processing on the surface of the substrate 3 with a rinse liquid (rinse processing step).

In the liquid processing step, as illustrated in FIG. 5B, the controller 14 moves the deionized water supply nozzle 26 to the start position above the central portion of the substrate 3 in a state where the substrate 3 is continuously rotated by rotating the turntable 17 at a predetermined rotation speed. Thereafter, the deionized water whose flow rate has been adjusted to a predetermined flow rate by the flow rate adjustor 33 is supplied as the rinse liquid from the deionized water source 32 to the deionized water supply nozzle 26, and ejected from the deionized water supply nozzle 26 toward the surface of the substrate 3. Thus, the surface of the substrate 3 is rinsed with the rinse liquid by rinsing away the processing liquid on the surface of the substrate 3 with the rinse liquid. The rinse liquid supplied to the substrate 3 is shaken off to the outside of the outer peripheral edge of the substrate 3 by the centrifugal force of the rotating substrate 3, recovered by the recovery cup 40, and discharged to the outside from the drain 41. After the rinse liquid is supplied for a predetermined time, the ejection of the rinse liquid is stopped by the flow rate adjustor 33. As such, in the rinse processing step, the deionized water supply nozzle 26, the flow rate adjustor 33, and the deionized water source 32 mainly function as the rinse liquid supply unit.

Next, the substrate liquid processing apparatus 1 performs a replacement processing on the surface of the substrate 3 with a replacement promoting liquid (first replacement processing step).

In the first replacement processing step, as illustrated in FIG. 6A, the controller 14 moves the IPA supply nozzle 27 to the start position above the central portion of the substrate 3 in a state where the substrate 3 is continuously rotated by rotating the turntable 17 at a predetermined rotation speed. Thereafter, the IPA whose flow rate has been adjusted to a predetermined flow rate by the flow rate adjustor 35 is supplied as the replacement promoting liquid from the IPA source 34 to the IPA supply nozzle 27, and ejected from the IPA supply nozzle 27 toward the surface of the substrate 3. Therefore, the rinse liquid on the surface of the substrate 3 is replaced with IPA, which may be then replaced with the water-repellent liquid to be supplied thereafter. The IPA supplied to the substrate 3 is shaken off to the outside of the outer peripheral edge of the substrate 3 by the centrifugal force of the rotating substrate 3, recovered by the recovery cup 40, and discharged to the outside from the drain 41. After the IPA is supplied for a predetermined time, the ejection of the IPA is stopped by the flow rate adjustor 35. As such, in the first replacement processing step, the IPA supply nozzle 27, the flow rate adjustor 35, and the IPA source 34 mainly function as the replacement promoting liquid supply unit. The rinse liquid (deionized water) and the replacement promoting liquid (IPA) may be ejected from the same nozzle or different nozzles, and a mixing ratio of the rinse liquid and the replacement promoting liquid may be changed stepwise, or gradually and continuously at the time of transition from the rinse processing step to the first replacement processing step. Here, “mixing” includes both the mixing before the ejection from the nozzle and the mixing on the wafer W after the ejection. In the latter case, the “mixing ratio” is a ratio of the ejection flow rates from the respective nozzles. When the mixing ratio is changed in this manner, the rinse processing step and the first replacement processing step may be performed at the same time. Thus, the time required for the processing may be shortened.

Next, the substrate liquid processing apparatus 1 performs a water-repellency processing on the surface of the substrate 3 with a water-repellent liquid (water-repellency processing step).

In the water-repellency processing step, as illustrated in FIG. 6B, the controller 14 moves the water-repellent liquid supply nozzle 28 to the start position above the central portion of the substrate 3. Thereafter, the water-repellent liquid whose flow rate has been adjusted to a predetermined flow rate by the flow rate adjustor 37 is supplied from the water-repellent liquid source 36 to the water-repellent supply nozzle 28, and ejected from the water-repellent liquid supply nozzle 28 toward the surface of the substrate 3. Thus, the surface of the substrate 3 is imparted with water-repellency. The water-repellent liquid supplied to the substrate 3 is shaken off to the outside of the outer peripheral edge of the substrate 3 by the centrifugal force of the rotating substrate 3, recovered by the recovery cup 40, and discharged to the outside from the drain 41. After the water-repellent liquid is supplied for a predetermined time, the ejection of the water-repellent liquid is stopped by the flow rate adjustor 37. As such, in the water-repellency processing step, the water-repellent liquid supply nozzle 28, the flow rate adjustor 37, and the water-repellent liquid source 36 mainly function as the water-repellent liquid supply unit. In the water-repellency processing step, the controller 14 selects CDA as a gas to be supplied from the FFU 42, and supplies the CDA to the processing chamber 15 to reduce the humidity inside the processing chamber 15.

Next, the substrate liquid processing apparatus 1 performs a replacement processing on the surface of the substrate 3 with a replacement promoting liquid (second replacement processing step).

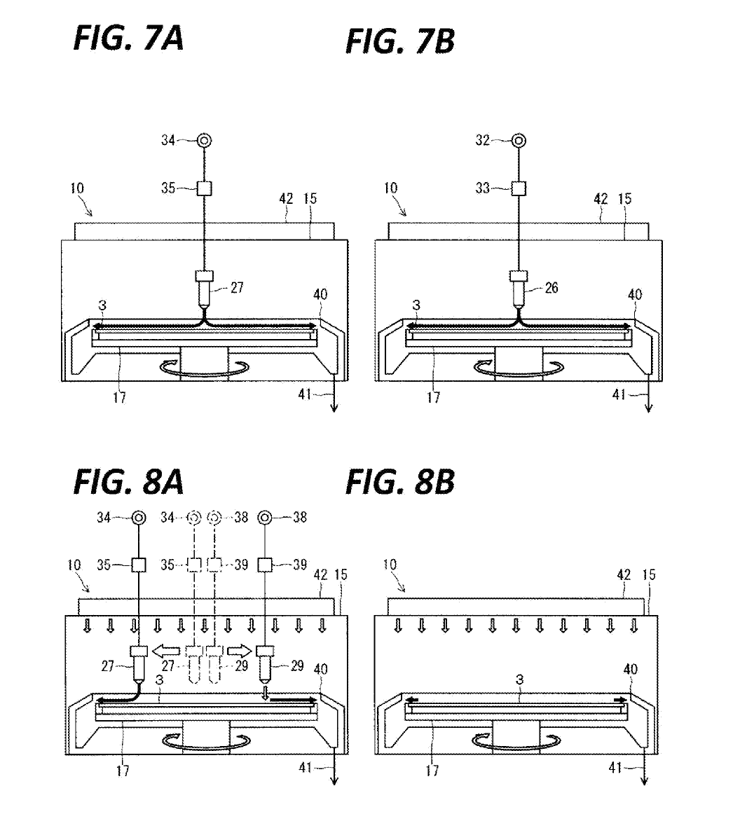

In the second replacement processing step, as illustrated in FIG. 7A, the controller 14 moves the IPA supply nozzle 27 to the start position above the central portion of the substrate 3 in a state where the substrate 3 is continuously rotated by rotating the turntable 17 at a predetermined rotation speed. Thereafter, the IPA whose flow rate has been adjusted to a predetermined flow rate by the flow rate adjustor 35 is supplied from the IPA source 34 to the IPA supply nozzle 27, and ejected from the IPA supply nozzle 27 toward the surface of the substrate 3. Thus, the water-repellent liquid on the surface of the substrate 3 is replaced with IPA. The IPA supplied to the substrate 3 is shaken off to the outside of the outer peripheral edge of the substrate 3 by the centrifugal force of the rotating substrate 3, recovered by the recovery cup 40, and discharged to the outside from the drain 41. After the IPA is supplied for a predetermined time, the ejection of the IPA is stopped by the flow rate adjustor 35. As such, in the second replacement processing step, the IPA supply nozzle 27, the flow rate adjustor 35, and the IPA source 34 mainly function as the replacement promoting liquid supply unit. Also, in the water-repellency processing step, the controller 14 selects CDA as a gas to be supplied from the FFU 42, and supplies the CDA to the processing chamber 15 to reduce the humidity inside the processing chamber 15.

Next, the substrate liquid processing apparatus 1 performs a cleaning processing on the surface of the substrate 3 with a cleaning liquid (cleaning processing step).

In the cleaning processing step, as illustrated in FIG. 7B, the controller 14 moves the deionized water supply nozzle 26 to the start position above the central portion of the substrate 3. Thereafter, the deionized water whose flow rate has been adjusted to a predetermined flow rate by the flow rate adjustor 33 is supplied as the cleaning liquid from the deionized water source 32 to the deionized water supply nozzle 26, and ejected from the deionized water supply nozzle 26 toward the surface of the substrate 3. Thus, the surface of the substrate 3 is cleaned with the cleaning liquid. When the substrate 3 is subjected to a water-repellency processing with the water-repellent liquid, impurities may remain on the surface of the substrate 3 after the water-repellency processing because the water-repellent liquid contains many impurities. Thus, the impurities remaining on the surface of the substrate 3 may be removed by cleaning the substrate 3, which has been subjected to the water-repellency processing, with the cleaning liquid. The cleaning liquid supplied to the substrate 3 is shaken off to the outside of the outer peripheral edge of the substrate 3 by the centrifugal force of the rotating substrate 3, recovered by the recovery cup 40, and discharged to the outside from the drain 41. After the cleaning liquid is supplied for a predetermined time, the ejection of the cleaning liquid is stopped by the flow rate adjustor 33. As such, in the cleaning processing step, the deionized water supply nozzle 26, the flow rate adjustor 33, and the deionized water source 32 mainly function as the cleaning liquid supply unit.

The replacement promoting liquid (IPA) and the cleaning liquid (deionized water) may be ejected simultaneously from the same nozzle or different nozzles at the time of transition from the second replacement processing step to the cleaning processing step. Therefore, the surface of the substrate 3 may be suppressed from being exposed during the switching from the replacement promoting liquid to the cleaning liquid so that the surface of the substrate 3 may not come into contact with the surrounding atmosphere (surrounding gas). At this time, the mixing ratio of the replacement promoting liquid and the cleaning liquid (also in this case, “mixing” includes both mixing before the ejection from the nozzle and mixing on the wafer W after the ejection) may be changed stepwise, or gradually and continuously. Therefore, since the surface tension of the liquid present on the surface of the substrate 3 is changed gradually, the surface of the substrate 3 may be easily suppressed from being exposed to outside air, as compared with a case where the surface tension is changed abruptly. For example, the mixing ratio of the replacement promoting liquid and the cleaning liquid is set to be 1:0 at the beginning of the supply, and the supply amount of the cleaning liquid is increased with the lapse of time to reduce the supply amount of the replacement promoting liquid. Thereafter, when the mixing ratio reaches a predetermined mixing ratio, the supply is performed for a predetermined time at that ratio. Then, the supply amount of the cleaning liquid is increased stepwise or continuously, and the supply amount of the replacement promoting liquid is decreased.

Further, IPA serving as the replacement promoting liquid may be contained in the cleaning liquid and supplied at the time of the cleaning processing step. As a result, the cleaning liquid easily permeates into the pattern of the water-repellent substrate 3, thereby improving the cleaning effect. Further, in this case, after the IPA containing cleaning liquid is supplied, only the cleaning liquid may be supplied. When the cleaning liquid is newly supplied in a state where the IPA containing cleaning liquid permeates into the pattern, the newly supplied cleaning liquid also easily penetrates into the pattern. Thus, the cleaning effect may be further improved. In the cleaning processing step, the controller 14 selects clean air as a gas to be supplied from the FFU 42, and supplies the clean air to the processing chamber 15 to increase the humidity inside the processing chamber 15.

Here, the cleaning liquid used in the cleaning processing step is not limited to deionized water, but functional water may also be used. As the functional water, an alkaline liquid may be used, and examples of the alkaline liquid include alkaline (preferably pH 8 or more) electrolytic ionized water, ammonia water which is diluted to 1 ppm to 20 ppm, hydrogen water, and ozone water. Thus, the impurities remaining on the surface of the substrate 3 may be further removed by cleaning the substrate 3, which has been subjected to the water-repellency processing, with the functional water, as compared with the case of cleaning with the deionized water.

Next, the substrate liquid processing apparatus 1 performs a drying processing to dry the surface of the substrate 3 (drying processing step). The drying processing step includes a drying liquid supply step of supplying a drying liquid to be replaced with the cleaning liquid to the substrate 3 and a drying liquid removal step of removing the drying liquid supplied to the substrate 3 from the substrate 3. As the drying liquid, a liquid having a higher volatility and lower surface tension than the cleaning liquid is used. Here, deionized water is used as the cleaning liquid, and IPA is used as the drying liquid.

In the drying processing step, as illustrated in FIG. 8A, the controller 14 moves the IPA supply nozzle 27 and the inert gas supply nozzle 29 to the start position above the central portion of the substrate 3 in a state where the substrate 3 is continuously rotated by rotating the turntable 17 at a predetermined rotation speed. Thereafter, the IPA whose flow rate has been adjusted to a predetermined flow rate by the flow rate adjustor 35 is supplied as the drying liquid from the IPA source 34 to the IPA supply nozzle 27, and ejected from the IPA supply nozzle 27 toward the surface of the substrate 3. In addition, the inert gas whose flow rate has been adjusted to a predetermined flow rate by the flow rate adjustor 39 (here, nitrogen gas) is supplied from the inert gas source 38 to the inert gas supply nozzle 29, and ejected from the inert gas supply nozzle 29 toward the surface of the substrate 3. Then, the IPA supply nozzle 27 and the inert gas supply nozzle 29 are moved from the start position above the substrate 3 toward a position above the outer peripheral edge. The moving direction of the two nozzles 27 and 29 may be the reverse direction or the same direction, but the IPA supply nozzle 27 is always positioned radially outward of the inert gas supply nozzle 29. Accordingly, the IPA ejected from the IPA supply nozzle 27 to the substrate 3 is forcibly moved toward the outer peripheral edge of the substrate 3 by the inert gas ejected from the inert gas supply nozzle 29. Therefore, the drying of the substrate 3 may be facilitated.

In this manner, the cleaning liquid on the surface of the substrate 3 is replaced with the drying liquid by supplying IPA to the substrate 3. The drying liquid supplied to the substrate 3 is shaken off to the outside of the outer peripheral edge of the substrate 3 by the centrifugal force of the rotating substrate 3, recovered by the recovery cup 40, and discharged to the outside from the drain 41. After the drying liquid is supplied for a predetermined time, the ejection of the drying liquid is stopped by the flow rate adjustor 35. As such, in the drying liquid supply step, the IPA supply nozzle 27, the flow rate adjustor 35, and the IPA source 34 mainly function as the drying liquid supply unit. In the drying liquid supply step, the controller 14 supplies the drying liquid to the substrate 3 at a flow rate lower than the flow rate of the replacement promoting liquid in the first replacement processing step.

The cleaning liquid (deionized water) and the drying liquid (IPA) may be ejected simultaneously from the same nozzle or different nozzles at the time of transition from the cleaning processing step to the drying processing step. Therefore, the surface of the substrate 3 may be suppressed from being exposed and coming into contact with the surrounding atmosphere (surrounding gas). At this time, a mixing ratio of the cleaning liquid and the drying liquid (also in this case, “mixing” includes both mixing before the ejection from the nozzle and mixing on the wafer W after the ejection) may be changed stepwise, or gradually and continuously. Therefore, since the surface tension of the liquid present on the surface of the substrate 3 is changed gradually, the surface of the substrate 3 may be easily suppressed from being exposed to outside air, as compared with a case where the surface tension is changed abruptly. For example, the mixing ratio of the cleaning liquid and the drying liquid is set to be 1:0 at the beginning of the supply, and the supply amount of the drying liquid is increased with the lapse of time to reduce the supply amount of the cleaning liquid. Thereafter, when the mixing ratio reaches a predetermined mixing ratio, the supply is performed for a predetermined time at that ratio. Then, the supply amount of the drying liquid is increased stepwise or continuously, and the supply amount of the cleaning liquid is decreased.

In the drying liquid removal step, as illustrated in FIG. 8B, the controller 14 continuously rotates the substrate 3 by rotating the turntable 17 at a predetermined rotation speed (a rotation speed higher than the rotation speed in the liquid processing step, the rinse processing step, the water-repellency processing step, and the cleaning processing step). Thus, the drying liquid remaining on the substrate 3 is shaken off to the outside of the outer peripheral edge of the substrate 3 by the action of the centrifugal force of the rotating substrate 3, and removed from the surface of the substrate 3 so that the surface of the substrate 3 is dried. In the drying liquid removal step, the nozzle group 23 (including the processing liquid supply nozzle 25, the deionized water supply nozzle 26, the IPA supply nozzle 27, the water-repellent liquid supply nozzle 28, and the inert gas supply nozzle 29) is retreated to the standby position outside the outer periphery of the turntable 17. Further, in the drying processing step, the controller 14 selects CDA as a gas to be supplied from the FFU 42 to the processing chamber, so that the humidity inside the processing chamber 15 is reduced as compared with the humidity in the cleaning processing step. Therefore, the drying of the substrate 3 is facilitated.

Finally, the substrate liquid processing apparatus 1 delivers the substrate 3 from the substrate liquid processing unit 10 to the substrate conveyance device 9 (substrate delivery step).

In the substrate delivery step, the controller 14 moves up the turntable 17 to a predetermined position. Then, the substrate 3 held by the turntable 17 is delivered to the substrate conveyance device 9. Thereafter, the turntable 17 is moved down to a predetermined position.

As described above, in the substrate liquid processing apparatus 1 (the substrate liquid processing method performed by the substrate liquid processing apparatus 1), the drying processing of the substrate 3 is performed by cleaning the substrate 3, which has been subjected to the water-repellency processing with the water-repellent liquid, with the cleaning liquid, and then, replacing the cleaning liquid having a higher volatility than that of the cleaning liquid to remove the drying liquid from the substrate 3.

As such, when the substrate 3 is subjected to the water-repellency processing with the water-repellent liquid, a large amount of impurities contained in the water-repellent liquid contaminates the substrate 3. Thus, after the water-repellency processing, the substrate 3 is cleaned with the cleaning liquid such as, for example, deionized water. Therefore, the impurities contained in the water-repellent liquid may be removed from the surface of the substrate 3. However, since the surface of the substrate 3 is imparted with water-repellency, the cleaning liquid is in the form of droplets on the surface of the substrate 3. When the substrate 3 is dried as it is by rotation at a high speed, a watermark is formed on the surface of the substrate 3 by the droplet-shaped cleaning liquid. Thus, the substrate 3 cannot be satisfactorily dried. Therefore, when the cleaning liquid on the surface of the substrate 3 is replaced with a drying liquid having a higher volatility than that of the cleaning liquid, and the substrate 3 is then dried by rotation at a high speed, the drying liquid may be smoothly removed from the surface of the substrate 3. Thus, the substrate 3 may be satisfactorily dried.

In the substrate liquid processing apparatus 1, when changing the type of the liquid used for processing the substrate 3, the processing with the subsequent liquid (e.g., the drying processing with IPA) is started after the processing with the preceding liquid (e.g., the cleaning processing with deionized water) is completed. However, the processing with the subsequent liquid may also be started during the processing with the preceding liquid. For example, a case of transition from a cleaning processing step performed for cleaning impurities contained in a water-repellent liquid to a drying processing step with IPA will be described below.

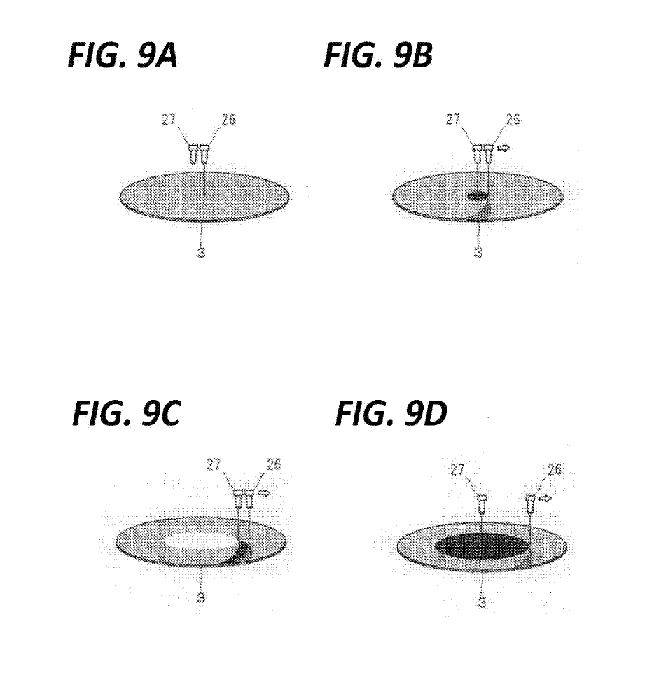

First, as illustrated in FIG. 9A, the controller 14 moves the deionized water supply nozzle 26 to the start position above the central portion of the substrate 3 in a state where the substrate 3 is continuously rotated by rotating the turntable 17 at a predetermined rotation speed, and moves the IPA supply nozzle 27 to a position adjacent to the deionized water supply nozzle 26. Then, deionized water is ejected from the deionized water supply nozzle 26 toward the center of the surface of the substrate 3. Then, as illustrated in FIG. 9B, the deionized water supply nozzle 26 is moved from a position above the central portion of the substrate 3 toward the outside of the outer periphery of the substrate 3 while ejecting the deionized water, and the IPA supply nozzle 27 is moved together with the deionized water supply nozzle 26. When the IPA supply nozzle 27 is positioned above the central portion of the substrate 3, IPA is ejected from the IPA supply nozzle 27 toward the center of the substrate 3 as a drying liquid. At that time, the flow rate and/or the rotation speed are controlled such that a streak-like flow is formed on the surface of the substrate 3. In order to form the streak-like flow, the rotation speed of the substrate 3 may be lower than that in the cleaning treatment step, or the supply amount of the deionized water may be reduced. In particular, reducing the supply amount of the deionized water is more desirable as compared with lowering the rotational speed, because it leads to reduction in consumption of the deionized water. The region through which the streak-like flow passes is covered with a liquid film of the deionized water which is thinner than the liquid film of the deionized water in the cleaning processing step. Then, as illustrated in FIG. 9C, the deionized water supply nozzle 26 and the IPA supply nozzle 27 are moved toward the upper side of the outer peripheral edge of the substrate 3. At that time, the deionized water supplied from the deionized water supply nozzle 26 flows toward the outer peripheral edge of the substrate 3 while maintaining the streak-like flow on the surface of the substrate 3. Further, since a predetermined amount of IPA is supplied from the IPA supply nozzle 27 together with the deionized water, a streak-like flow including IPA and deionized water is formed. Thus, the impurities remaining on the surface of the substrate 3 may be removed by the deionized water contained in the streak-like flow. Furthermore, since IPA having a low surface tension is mixed, it is possible to form a streak-like flow which is not discontinued. Thus, impurities remaining on the surface of the substrate 3 may be uniformly removed. Further, the deionized water easily permeates into the pattern of the substrate 3, thereby improving the cleaning effect. In the region through which the streak-like flow passes, the liquid film of the deionized water is gradually replaced with a liquid film of IPA having a surface tension lower than that of the deionized water, so that the surface of the substrate 3 is not exposed. Further, the concentration of IPA is high at the upstream end of the streak-like flow. Thus, the drying region spreads concentrically on a region inward from the IPA supply position. Therefore, since the cleaning processing and the drying processing may be performed by the streak-like flow at the same time, the time of the drying processing may be shortened, and thus, the throughput of the substrate liquid processing apparatus 1 may be enhanced. Furthermore, the cleaning effect may be enhanced by forming the streak-like flow.

As illustrated in FIG. 9D, the deionized water supply nozzle 26 is moved from a position above the central portion of the substrate 3 toward the outside of the outer peripheral edge of the substrate 3 while ejecting the deionized water, and the IPA supply nozzle 27 is positioned above the central portion of the substrate 3 such that IPA is ejected from the IPA supply nozzle 27 toward the center of the substrate 3 as a drying liquid. At that time, the deionized water supplied from the deionized water supply nozzle 26 forms a streak-like flow including IPA and deionized water flowing toward the outer peripheral edge of the substrate 3 while maintaining the streak-like flow on the surface of the substrate 3. Thus, the impurities remaining on the surface of the substrate 3 may be removed by the deionized water contained in the streak-like flow. Further, since IPA having a low surface tension is mixed, it is possible to form a streak-like flow which is not discontinued. In addition, since the streak-like flow is moved from the central portion of the substrate 3 toward the outer peripheral edge, impurities remaining on the surface of the substrate 3 may be uniformly removed. Further, the deionized water easily permeates into the pattern of the substrate 3, thereby improving the cleaning effect. The region through which the streak-like flow passes is covered with a liquid film of the deionized water, which is thinner than the liquid film of the deionized water in the cleaning processing step. However, since the liquid film of the deionized water is gradually replaced with a liquid film of IPA, the surface of the substrate 3 is not exposed. Further, since the IPA is ejected from the upper side of the central portion of the substrate 3, the region on the substrate 3 inward from the upstream end of the streak-like flow is covered with the liquid film of the IPA, so that the surface of the substrate 3 is not exposed. According to the exemplary embodiment, the drying liquid removal step may be performed immediately after the deionized water supply nozzle 26 reaches the outer periphery of the substrate 3. Since this drying liquid removal step is the same as the drying liquid removal step described in the previous exemplary embodiment, descriptions thereof are omitted.

As described above, since the drying liquid removal step may be performed immediately after the cleaning processing by the streak-like flow, the time of the drying processing may be shortened, and thus, the throughput of the substrate liquid processing apparatus 1 may be enhanced. Further, the cleaning effect may be enhanced by forming the streak-like flow after the cleaning processing step. Further, the cleaning processing may be performed by the streak-like flow without exposing the surface of the substrate 3.

1. A substrate liquid processing method comprising:
performing a liquid processing step of liquid-processing a substrate with a processing liquid, a rinse processing step of rinsing the liquid-processed substrate with a rinse liquid, and a water-repellency processing step of imparting water-repellency to the rinsed substrate with a water-repellent liquid;
then, performing a replacement processing step of replacing the water-repellency-imparted substrate with a replacement promoting liquid, and a cleaning processing step of cleaning the water-repellency-imparted substrate with a cleaning liquid; and
then, performing a drying processing step of replacing the cleaning liquid with a drying liquid having a higher volatility than that of the cleaning liquid and removing the drying liquid from the substrate.

2. The substrate liquid processing method of claim 1, wherein the cleaning liquid is deionized water, and
the drying liquid and the replacement promoting liquid are isopropyl alcohol (IPA).

3. The substrate liquid processing method of claim 1, wherein a flow rate of the replacement promoting liquid supplied to the substrate in the replacement processing step is higher than a flow rate of the drying liquid supplied to the substrate in the drying processing step.

4. The substrate liquid processing method of claim 1, wherein in the drying processing step, the drying liquid is supplied to the substrate in a lower humidity state than that of the cleaning treatment step.

5. The substrate liquid processing method of claim 1, wherein the replacement processing step and the cleaning processing step are performed at the same time.

6. The substrate liquid processing method of claim 1, wherein the replacement promoting liquid, the cleaning liquid, and the drying liquid are supplied to the substrate from the same nozzle.

7. The substrate liquid processing method of claim 1, wherein the replacement promoting liquid and the cleaning liquid are supplied to the substrate by changing a mixing ratio thereof stepwise or continuously at a time of transition from the replacement processing step to the cleaning processing step.

8. The substrate liquid processing method of claim 1, wherein the cleaning liquid and the drying liquid are supplied to the substrate by changing a mixing ratio thereof stepwise or continuously at a time of transition from the cleaning processing step to the drying processing step.

9. The substrate liquid processing method of claim 1, wherein the drying processing step includes steps of: forming, on the substrate, a streak-like flow of the cleaning liquid toward an outer peripheral edge of the substrate at a supply position where the cleaning liquid is supplied onto the substrate; and supplying the drying liquid to a position closer to a central side of the substrate than the supply position of the cleaning liquid.

10. The substrate liquid processing method of claim 9, wherein the step of forming the streak-like flow of the cleaning liquid includes a step of moving the supply position of the cleaning liquid from the central side of the substrate to the outer peripheral side.

11. A substrate liquid processing apparatus comprising:
a substrate holding unit that holds a substrate;
a processing liquid supply unit that supplies a processing liquid to the substrate;
a rinse liquid supply unit that supplies a rinse liquid to the substrate liquid-processed with the processing liquid;
a water-repellent liquid supply unit that supplies a water-repellent liquid to the substrate rinsed with the rinse liquid;
a replacement promoting liquid supply unit that supplies a replacement promoting liquid to the substrate imparted with water-repellency with the water-repellent liquid;
a cleaning liquid supply unit that supplies a cleaning liquid to the substrate processed with the replacement promoting liquid;
a drying liquid supply unit that supplies a drying liquid having a higher volatility that that of the cleaning liquid to the substrate cleaned with the cleaning liquid; and
a controller that performs a control to supply the replacement promoting liquid from the replacement promoting liquid supply unit to the substrate imparted with water-repellency with the water-repellent liquid, supply the cleaning liquid from the cleaning liquid supply unit to the substrate, supply the drying liquid from the drying liquid supply unit to the substrate, and then, remove the drying liquid from the substrate.

12. The substrate liquid processing apparatus of claim 11, wherein the controller performs a control to supply the replacement processing liquid from the replacement promoting liquid supply unit to the substrate at a flow rate higher than a flow rate of the drying liquid to be supplied from the drying liquid supply unit to the substrate.

13. The substrate liquid processing apparatus of claim 11, further comprising:
a dry air supply unit that supplies dry air to the substrate,
wherein the controller causes the dry air to be supplied from the dry air supply unit to the substrate when the drying liquid is supplied from the drying liquid supply unit to the substrate.

14. The substrate liquid processing apparatus of claim 11, wherein the controller performs a control to supply the replacement promoting liquid from the replacement promoting liquid supply unit to the substrate and simultaneously supply the cleaning liquid from the cleaning liquid supply unit.

15. The substrate liquid processing apparatus of claim 11, wherein the replacement promoting liquid, the cleaning liquid, and the drying liquid are supplied to the substrate from the same nozzle.

16. The substrate liquid processing apparatus of claim 11, wherein the replacement promoting liquid and the cleaning liquid are supplied to the substrate by changing a mixing ratio thereof stepwise or continuously at a time of transition from the supply of the replacement processing liquid to the supply of the cleaning processing liquid.

17. The substrate liquid processing apparatus of claim 11, wherein the cleaning liquid and the drying liquid are supplied to the substrate by changing a mixing ratio thereof stepwise or continuously at a time of transition from the supply of the cleaning processing liquid to the supply of the drying processing liquid.

18. The substrate liquid processing apparatus of claim 11, wherein, at the time of transition from supply of the cleaning liquid to supply of the drying liquid, a streak-like flow of the cleaning liquid is formed on the substrate at a supply position where the cleaning liquid is supplied onto the substrate toward an outer peripheral edge of the substrate, and the drying liquid is supplied to a position closer to a central side of the substrate than the supply position of the cleaning liquid.

19. The substrate liquid processing apparatus of claim 18, wherein the supply position of the cleaning liquid forming the streak-like flow is moved from the central side of the substrate to the outer peripheral side.

20. A non-transitory computer-readable storage medium that stores a substrate liquid processing program that, when executed, to cause a computer to perform a processing on a substrate using a substrate liquid processing apparatus including: a substrate holding unit that holds a substrate; a processing liquid supply unit that supplies a processing liquid to the substrate; a rinse liquid supply unit that supplies a rinse liquid to the substrate liquid-processed with the processing liquid; a water-repellent liquid supply unit that supplies a water-repellent liquid to the substrate rinsed with the rinse liquid; a replacement promoting liquid supply unit that supplies a replacement promoting liquid to the substrate imparted with water-repellency with the water-repellent liquid; a cleaning liquid supply unit that supplies a cleaning liquid to the substrate processed with the replacement promoting liquid; a drying liquid supply unit that supplies a drying liquid having a higher volatility that that of the cleaning liquid to the substrate cleaned with the cleaning liquid; and a controller that controls the units,
wherein a control is performed to supply the replacement promoting liquid from the replacement promoting liquid supply unit to the substrate imparted with water-repellency with the water-repellent liquid, supply the cleaning liquid from the cleaning liquid supply unit to the substrate, supply the drying liquid from the drying liquid supply unit to the substrate, and then, remove the drying liquid from the substrate.
